(19) United States
(12) Patent Application Publication
(10) Pub. No.: US 2008/0083625 A1
(43) Pub. Date: Apr. 10, 2008

(54) Method for Manufacturing Semiconductor Device

(76) Inventor: SANG CHUL KIM, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/863,488

(22) Filed: Sep. 28, 2007

(30) Foreign Application Priority Data
Oct. 9, 2006 (KR) 10-2006-0097750

(51) Int. Cl. C25D 7/12; H01L 21/311

(52) U.S. Cl. 205/157; 438/694

(57) ABSTRACT

A method for manufacturing a semiconductor device is provided. The method can include forming a pattern for a copper line on a semiconductor substrate, forming a barrier metal layer on the pattern, removing a natural oxide layer from the barrier metal layer using a basic compound, and depositing copper ions on the barrier metal layer. A copper seed layer is not necessary.

### CROSS-REFERENCE TO RELATED APPLICATION

The present application claims the benefit under 35 U.S.C. §119 of Korean Patent Application No. 10-2006-0097750, filed Oct. 9, 2006, which is hereby incorporated by reference in its entirety.

### BACKGROUND

As the technology of semiconductor devices becomes more developed, newer processes for forming finer patterns have been introduced and optimization of existing processes has been in demand.

A process of filling a material, such as an insulating material, into a fine pattern (hereinafter, referred to as gapfill process) is often very sensitive to pattern shapes. The pattern shape can include the pattern area, the pattern width, the pattern depth, and the sidewall slope of a pattern.

In particular, pattern widths, which are often a representative value of the technology node of a device, have been reduced to between several hundreds to several tens of nanometers.

As semiconductor patterns shrink in size, barrier metals and seed copper layers are typically made thinner accordingly.

Referring to FIG. 1, in a related art semiconductor device fabrication process, a copper seed layer 30 is deposited by a physical vapor deposition (PVD) process. An overhang A often occurs due to physical limitations of the process, thereby causing a gapfill defect H inside the pattern when copper is deposited by a subsequent electrolytic plating process, as illustrated in FIG. 2.

Therefore, it can be advantageous to attempt to inhibit the formation of an overhang A by directly depositing copper on a barrier metal without deposition of a copper seed layer 30.

However, barrier metal layers, often formed of titanium (Ti), titanium nitride (TiN), tantalum (Ta), tantalum nitride (TaN), or tungsten (W), are generally susceptible to oxidation when exposed to air. This results in the formation of an oxide layer on the barrier metal layer. The oxide layer on the barrier metal increases the resistance of the barrier metal, thereby impeding current flow when copper is deposited by a subsequent electrolytic plating process. Accordingly, contact defects between the copper and the barrier metal are often formed.

Thus, there exists a need in the art for an improved method of fabricating a semiconductor device.

### BRIEF SUMMARY

Embodiments of the present invention provide methods for manufacturing a semiconductor device that improve gapfill capability of copper by directly forming copper on a barrier metal without forming a copper seed layer.

In an embodiment, a method for manufacturing a semiconductor device can include: forming a pattern for a copper line on a semiconductor substrate; forming a barrier metal layer on the pattern; using a basic compound to remove a natural oxide layer formed on the barrier metal layer; and forming a copper line by depositing copper ions on the barrier metal layer.

The details of one or more embodiments are set forth in the accompanying drawings and the detailed description. Other features will be apparent to one skilled in the art from the detailed description, the drawings, and the appended claims.

### BRIEF DESCRIPTION OF THE DRAWINGS

FIGS. 1 and 2 are cross-sectional views illustrating a related art method of forming a copper line.

FIG. 3 is a flowchart illustrating a method of forming a copper line according to an embodiment of the present invention.

FIG. 4 is a cross-sectional view illustrating a method of forming a copper line according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

As a pretreatment process, a wafer that has undergone rinsing and drying processes can be surface-treated to improve the adherence of the wafer. For example, the wafer can be surface-treated with hexamethyldisilazane. Thereafter, the wafer can be coated with a photoresist.

In an embodiment, a photoexposure apparatus, such as a stepper, can be used to project a predetermined image for a photoresist pattern onto the photoresist on the wafer. Photoexposure and development processes can be performed to form a photoresist pattern.

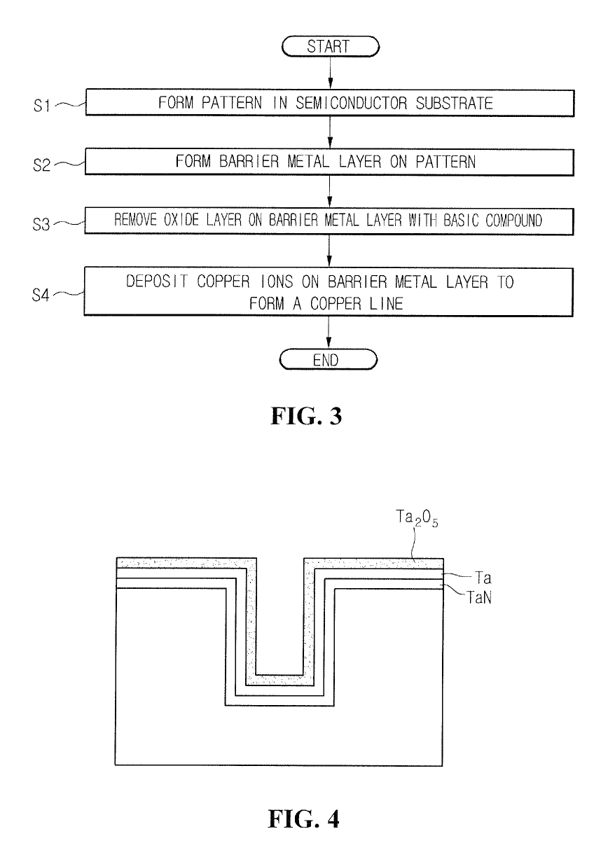

Then, referring to FIG. 3, a pattern for a copper line can be formed on a semiconductor substrate (S1). The pattern can be formed using any suitable method, for example, an etching process can be performed using the photoresist pattern as an etch mask to form the pattern.

Thereafter, a barrier metal layer can be formed on the pattern (S2) for inhibiting diffusion of ions, impurities, and heat. The barrier metal layer can be formed of titanium (Ti), titanium nitride (TiN), tantalum (Ta), tantalum nitride (TaN), tungsten (W), or any other suitable material known in the art. The barrier metal layer can be formed using any suitable process known in the art, for example, a physical vapor deposition (PVD) process.

In an embodiment, the barrier metal layer can be formed to have a bilayer structure configured with two layers. Referring to FIG. 4, the barrier metal layer can be a bilayer formed of TaN and Ta.

The barrier metal layer may be susceptible to oxidation when it is exposed to air.

Accordingly, a natural oxide layer may be formed on the barrier metal layer. Referring again to FIG. 4, in embodiments where the barrier metal layer is formed of a bilayer of TaN and Ta, the Ta oxidizes to form tantalum oxide (Ta₂O₅).

Hence, the natural oxide layer formed on the barrier metal layer can be removed (S3 of FIG. 3).

In an embodiment, the natural oxide layer can be removed using a sprayer in a cleaning chamber of a typical electrolytic plating apparatus known in the art. The natural oxide layer on the barrier metal layer can be removed using a basic compound. The basic compound can contain a hydroxide group (—OH) and can be, for example, potassium hydroxide (KOH), calcium hydroxide (Ca(OH)₂), sodium hydroxide (NaOH), or magnesium hydroxide (Mg(OH)₂).

In embodiments where the barrier metal is formed of a bilayer of Ta and TaN, a Ta₂O₅ oxide layer is often immediately produced when the barrier metal is exposed to air. The Ta₂O₅ oxide layer can be chemically removed by spraying a KOH aqueous solution with a sprayer in a cleaning chamber of an electrolytic plating apparatus.

For example, in one embodiment, a KOH aqueous solution can have a concentration of about 1 M and can be sprayed for about 0.5 seconds to about 1.5 seconds. The KOH can be sprayed about 6 hours after the barrier metal layer is formed. In these embodiments, the amount of the Ta₂O₅ that can be removed can be from about 90% to about 100%.

In an embodiment, the natural oxide layer can be removed by performing a process in a cleaning chamber of a typical electrochemical plating (ECP) apparatus. Accordingly, in this embodiment, an additional apparatus is not needed for removing the natural oxide. This leads to a decreased cost of the fabrication process.

Next, copper ions can be deposited on the barrier metal layer to form a copper line (S4 of FIG. 3).

In an embodiment, The copper line can be formed such that a copper electrode and a wafer can be used as an anode and a cathode, respectively, in an electrolytic cell. Power can then supplied to both the anode and the cathode to deposit copper ions released from the copper electrode on the pattern and the wafer surface.

According to embodiments of the present invention, fabrication cost for semiconductor devices can be reduced by omitting a related art process of depositing a copper seed layer.

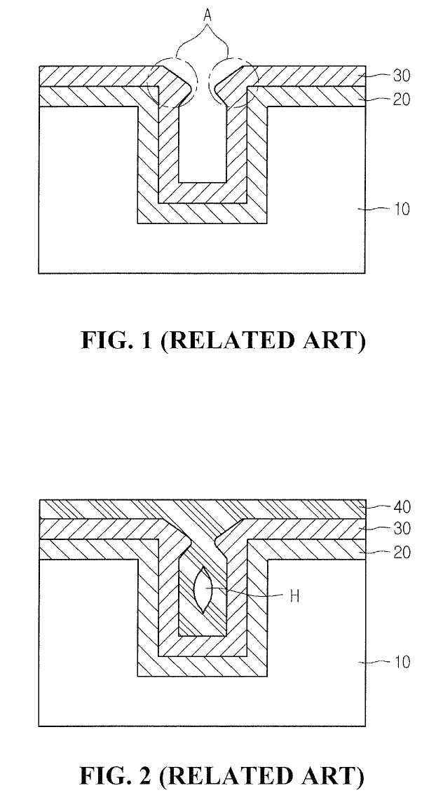

Additionally, embodiments of the present invention make it possible to inhibit the occurrence of an overhang (A of FIG. 1) which may be caused during the formation of a copper seed layer on a barrier metal layer. In particular, the process of forming the copper seed layer can be omitted.

Furthermore, an oxide layer, which may be formed on a barrier metal layer when no seed copper layer is formed, can be removed using a basic compound according to embodiments of the present invention.

Moreover, in an electrolytic plating method according to embodiments of the present invention, the yield of wafers can be maximized in a fabrication process by reducing manufacturing costs and avoiding gapfill defects.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
forming a pattern for a copper line on a semiconductor substrate;
forming a barrier metal layer on the pattern;
using a basic compound to remove at least a majority of a natural oxide layer formed on the barrier metal layer; and
forming a copper line by depositing copper ions on the barrier metal layer, wherein the copper ions are deposited after the majority of the natural oxide layer has been removed.

2. The method according to claim 1, wherein the majority of the natural oxide layer comprises at least 80% of the natural oxide layer.

3. The method according to claim 1, wherein the majority of the natural oxide layer comprises at least 90% of the natural oxide layer.

4. The method according to claim 1, wherein the majority of the natural oxide layer comprises about 100% of the natural oxide layer.

5. The method according to claim 1, wherein the barrier metal layer comprises titanium (Ti), titanium nitride (TiN), tantalum (Ta), tantalum nitride (TaN) or tungsten (W).

6. The method according to claim 1, wherein the barrier metal layer comprises a bilayer structure.

7. The method according to claim 6, wherein the bilayer structure comprises a TaN layer and a Ta layer.

8. The method according to claim 7, wherein the natural oxide layer comprises Ta₂O₅.

9. The method according to claim 8, wherein the basic compound comprises potassium hydroxide (KOH).

10. The method according to claim 9, wherein the basic compound comprises an aqueous solution of KOH with a KOH concentration of about 1 M.

11. The method according to claim 10, wherein using the basic compound comprises spraying the aqueous solution of KOH on the natural oxide layer for about 0.5 seconds to about 1.5 seconds.

12. The method according to claim 11, wherein the aqueous solution of KOH is sprayed about 6 hours after forming the barrier metal layer.

13. The method according to claim 9, wherein the majority of the natural oxide layer comprises about 90% to about 100% of the natural oxide layer.

14. The method according to claim 1, wherein the basic compound comprises KOH, calcium hydroxide (Ca(OH)₂), sodium hydroxide (NaOH), or magnesium hydroxide (Mg(OH)₂).

15. The method according to claim 1, wherein forming the copper line comprises supplying power to an anode and a cathode in an electrolytic cell to deposit copper ions released from the anode on the barrier metal layer.

16. The method according to claim 15, wherein the anode is a copper electrode, and wherein the cathode is the semiconductor substrate.

17. The method according to claim 1 wherein using a basic compound comprises using a sprayer in a cleaning chamber to spray the basic compound on the natural oxide layer.

18. The method according to claim 17, wherein the cleaning chamber is a cleaning chamber of an electrolytic planting apparatus.

19. The method according to claim 17, wherein the cleaning chamber is a cleaning chamber of an electrochemical plating apparatus.
